(19) United States
(12) Patent Application Publication
(10) Pub. No.: US 2024/0324420 A1
(43) Pub. Date: Sep. 26, 2024

(54) DISPLAY APPARATUS

(71) Applicants: Samsung Display Co., Ltd., Yongin-si (KR); UIF (University Industry Foundation), Yonsei University, Seoul (KR)

(72) Inventors: Younggu Kim, Yongin-si (KR); Kyungnam Kang, Seoul (KR); Donghyun Kim, Seoul (KR); Duckjong Suh, Yongin-si (KR); Bongsung Seo, Yongin-si (KR); Baekkyun Jeon, Yongin-si (KR); Hyunwoong Lee, Incheon (KR)

(21) Appl. No.: 18/604,380

(22) Filed: Mar. 13, 2024

(30) Foreign Application Priority Data
Mar. 24, 2023 (KR) 10-2023-0039045
May 16, 2023 (KR) 10-2023-0063255

(51) Int. Cl. H10K 59/80

(52) U.S. Cl. CPC H10K 59/8791; H10K 59/873

(57) ABSTRACT

A display apparatus includes: a substrate; a display element on the substrate, and including a pixel electrode, an emission layer, and an opposite electrode; a capping layer on the display element; a metal unit area including a plurality of metal patterns spaced from each other on the capping layer, each of the plurality of metal patterns having a thickness less than a wavelength of visible light; and an insulating layer buried in a separation area between the plurality of metal patterns.

### CROSS-REFERENCE TO RELATED APPLICATION

This application claims priority to and the benefit of Korean Patent Application Nos. 10-2023-0039045, filed on Mar. 24, 2023, and 10-2023-0063255, filed on May 16, 2023, in the Korean Intellectual Property Office, the entire disclosures of all of which are incorporated by reference herein.

### BACKGROUND

### 1. Field

Aspects of one or more embodiments of the present disclosure relate to a display apparatus.

### 2. Description of Related Art

An organic light-emitting device (OLED) used in a display apparatus is a display device that forms an image when holes injected from an anode and electrons injected from a cathode combine with each other in an organic emission layer formed between the anode and the cathode to emit light.

These OLEDs are widely used because they have excellent display characteristics, such as a wide viewing angle, fast response times, a low thickness, low manufacturing costs, and a high contrast.

An OLED used in a display apparatus may be divided into a bottom emission structure and a top emission structure. According to the top emission structure, light generated in an organic emission layer is emitted to the outside through a cathode.

The above information disclosed in this Background section is for enhancement of understanding of the background of the present disclosure, and therefore, it may contain information that does not constitute prior art.

### SUMMARY

One or more embodiments of the present disclosure are directed to a display apparatus having excellent anti-reflection characteristics. However, the present disclosure is not limited thereto, and the above and other aspects and features of the present disclosure will be apparent to those having ordinary skill in the art from the following description.

Additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a substrate; a display element on the substrate, and including a pixel electrode, an emission layer, and an opposite electrode; a capping layer on the display element; a metal unit area including a plurality of metal patterns spaced from each other on the capping layer, each of the plurality of metal patterns having a thickness less than a wavelength of visible light; and an insulating layer buried in a separation area between the plurality of metal patterns.

In an embodiment, the metal unit area may be repeatedly arranged along a first direction, and a second direction crossing the first direction, and a width of the metal unit area that is repeatedly arranged may be equal to or greater than 300 nm, and equal to or less than 1500 nm.

In an embodiment, the plurality of metal patterns may include a first metal pattern and a second metal pattern adjacent to each other in a first direction, each having a rectangular shape in a plan view.

In an embodiment, the metal unit area may be divided into first to fourth quadrants. A first sub-unit including the first metal pattern and the second metal pattern may be located in the first quadrant, a second sub-unit obtained by rotating the first sub-unit by 90 degrees counterclockwise may be located in the second quadrant, a third sub-unit obtained by rotating the first sub-unit by 180 degrees counterclockwise may be located in the third quadrant, and a fourth sub-unit obtained by rotating the first sub-unit by 270 degrees counterclockwise may be located in the fourth quadrant.

In an embodiment, an interval between the first metal pattern and the second metal pattern may be equal to or greater than 50 nm, and equal to or less than 500 nm.

In an embodiment, the thickness of each of the first metal pattern and the second metal pattern may be equal to or greater than 5 nm, and equal to or less than 100 nm.

In an embodiment, a width of each of the first metal pattern and the second metal pattern in the first direction may be equal to or greater than 20 nm, and equal to or less than 300 nm; a length of the first metal pattern in a second direction crossing the first direction may be equal to or greater than 100 nm, and equal to or less than 650 nm; and a length of the second metal pattern in the second direction may be equal to or greater than 50 nm, and equal to or less than 600 nm.

In an embodiment, each of the plurality of metal patterns may have a spherical shape, a cylindrical shape, or a stacked cylindrical shape.

In an embodiment, each of the plurality of metal patterns may include silver (Ag), gold (Au), aluminum (Al), tantalum (Ta), nickel (Ni), or a combination thereof.

In an embodiment, the display apparatus may further include a thin-film encapsulation layer between the capping layer and the plurality of metal patterns.

According to one or more embodiments of the present disclosure, a display apparatus includes: a substrate; a display element on the substrate, and including a pixel electrode, an emission layer, and an opposite electrode; a capping layer on the display element; a metal layer on the capping layer, and including a metal unit area including a plurality of through-patterns, each having a depth less than a wavelength of visible light; and an insulating layer buried in the plurality of through-patterns.

In an embodiment, the metal unit area may be repeatedly arranged along a first direction, and a second direction crossing the first direction, and a width of the metal unit area that is repeatedly arranged may be equal to or greater than 300 nm, and equal to or less than 1500 nm.

In an embodiment, the plurality of through-patterns may include a first through-pattern and a second through-pattern adjacent to each other in a first direction, each having a rectangular shape in a plan view.

In an embodiment, the metal unit area may be divided into first to fourth quadrants. A first sub-unit including the first through-pattern and the second through-pattern may be located in the first quadrant, a second sub-unit obtained by rotating the first sub-unit by 90 degrees counterclockwise may be located in the second quadrant, a third sub-unit obtained by rotating the first sub-unit by 180 degrees counterclockwise may be located in the third quadrant, and a fourth sub-unit obtained by rotating the first sub-unit by 270 degrees counterclockwise may be located in the fourth quadrant.

In an embodiment, an interval between the first through-pattern and the second through-pattern may be equal to or greater than 50 nm, and equal to or less than 500 nm.

In an embodiment, the depth of each of the first through-pattern and the second through-pattern may be equal to or greater than 5 nm, and equal to or less than 100 nm.

In an embodiment, a width of each of the first through-pattern and the second through-pattern in the first direction may be equal to or greater than 20 nm, and equal to or less than 300 nm; a length of the first through-pattern in a second direction crossing the first direction may be equal to or greater than 100 nm, and equal to or less than 650 nm; and a length of the second through-pattern in the second direction may be equal to or greater than 50 nm, and equal to or less than 600 nm.

In an embodiment, each of the plurality of through-patterns may have a spherical shape, a cylindrical shape, or a stacked cylindrical shape.

In an embodiment, the metal layer may include silver (Ag), gold (Au), aluminum (Al), tantalum (Ta), nickel (Ni), or a combination thereof.

In an embodiment, the display apparatus may further include a thin-film encapsulation layer between the capping layer and the metal layer.

The above and other aspects and features of the present disclosure will become more apparent from the detailed description, with reference to the drawings, the claims, and their equivalents.

The general and specific embodiments of the present disclosure described herein may be implemented by using a system, a method, a computer program, or a suitable combination thereof.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view schematically illustrating a part of a display apparatus, according to an embodiment;

FIG. 2 is an equivalent circuit diagram illustrating a pixel included in the display apparatus of FIG. 1;

FIG. 3 is a cross-sectional view schematically illustrating a part of a display apparatus, according to an embodiment;

FIG. 4 is a perspective view schematically illustrating an example of metal patterns;

FIG. 5 is a cross-sectional view schematically illustrating a portion of a display apparatus, according to an embodiment;

FIG. 6 is a plan view schematically illustrating an example of through-patterns;

FIG. 7 is a cross-sectional view schematically illustrating a portion of a display apparatus, according to an embodiment;

FIGS. 8A and 8B are graphs illustrating the reflectance of a display apparatus of an embodiment and the reflectance of a comparative example;

FIGS. 9 and 10 are plan views schematically illustrating an example of metal patterns; and

FIGS. 11A-11C are perspective views schematically illustrating some examples of metal patterns.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

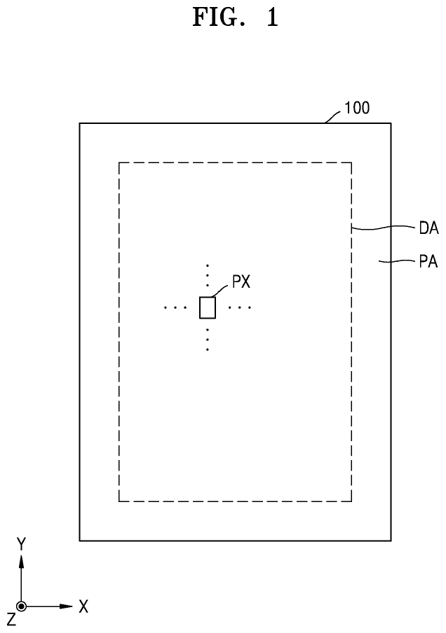

FIG. 1 is a plan view schematically illustrating a part of a display apparatus, according to an embodiment.

A display apparatus is a device for displaying an image, and may be a portable mobile device, such as a game player, a multimedia device, or a mini-PC. Examples of the display apparatus described in more detail below may include a liquid-crystal display, an electrophoretic display, an organic light-emitting display, an inorganic light-emitting display, a field-emission display, a surface-conduction electron-emitter display, a quantum dot display, a plasma display, and a cathode ray display. Although an organic light-emitting display apparatus is used as the display apparatus according to an embodiment, the present disclosure is not limited thereto, and any of the various suitable display apparatuses described above may be used.

As shown in FIG. 1, the display apparatus may include a display area DA where a plurality of pixels PX are located, and a peripheral area PA located outside the display area DA. In more detail, the peripheral area PA may entirely surround (e.g., around a periphery of) the display area DA. A substrate 100 included in the display apparatus may include the display area DA and the peripheral area PA.

Each pixel PX of the display apparatus is an area where light of a desired color (e.g., a certain or predetermined color) may be emitted, and the display apparatus may provide an image by using light emitted from the pixels PX. For example, each pixel PX may emit red light, green light, or blue light. The pixel PX may include a plurality of thin-film transistors and a storage capacitor for controlling a display element. The number of thin-film transistors included in one pixel may be variously modified as would be understood by those having ordinary skill in the art. For example, anywhere from one to seven thin-film transistors may be included in one pixel.

The display area DA may have any of various suitable polygonal shapes including a quadrangular shape as shown in FIG. 1. For example, the display area DA may have a rectangular shape in which a horizontal length is greater than a vertical length, a rectangular shape in which a horizontal length is less than a vertical length, or a square shape. As another example, the display area DA may have any of various suitable shapes, such as an elliptical shape or a circular shape.

The peripheral area PA may be a non-display area where no pixels PX are located. A driver or the like for applying an electrical signal or power to the pixels PX may be located in the peripheral area PA. Pads to which various electronic devices or printed circuit boards may be electrically connected may be located in the peripheral area PA. The pads may be located in the peripheral area PA to be spaced apart from each other, and may be electrically connected to a printed circuit board or an integrated circuit device. A thin-film transistor may also be provided in the peripheral area PA, and in this case, the thin-film transistor located in the peripheral area PA may be a part of a circuit unit (e.g., a controller or a control circuit) for controlling an electrical signal applied into the display area DA.

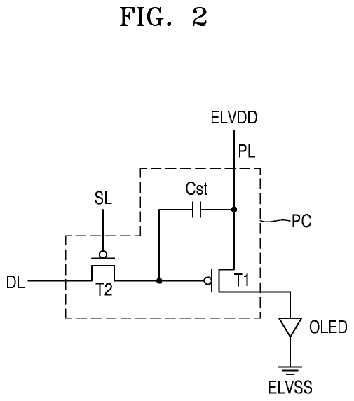

FIG. 2 is an equivalent circuit diagram illustrating a pixel (e.g., one pixel) PX included in the display apparatus of FIG. 1.

Referring to FIG. 2, one pixel PX may include a pixel circuit PC, and an organic light-emitting diode OLED electrically connected to the pixel circuit PC.

The pixel circuit PC may include a first thin-film transistor T1, a second thin-film transistor T2, and a storage capacitor Cst. The second thin-film transistor T2 may be a switching transistor that is connected to a scan line SL and a data line DL, and may be turned on by a switching signal input from the scan line SL to transmit a data signal input from the data line DL to the first thin-film transistor T1. The storage capacitor Cst may have one end electrically connected to the second thin-film transistor T2, and another end (e.g., the other end) electrically connected to a driving voltage line PL. The storage capacitor Cst may store a voltage corresponding to a difference between a voltage received from the second thin-film transistor T2 and a driving power supply voltage ELVDD supplied to the driving voltage line PL.

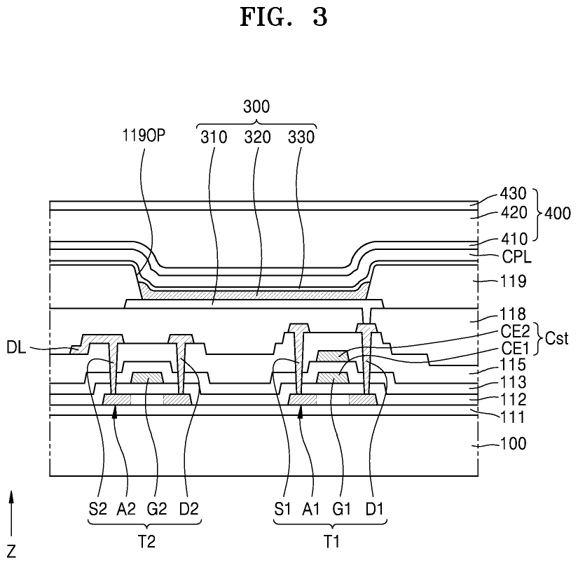

The first thin-film transistor T1 may be a driving transistor that is connected to the driving voltage line PL and the storage capacitor Cst, and may control a magnitude of a driving current flowing from the driving voltage line PL to the organic light-emitting diode OLED in response to a value of the voltage stored in the storage capacitor Cst. The organic light-emitting diode OLED may emit light having a desired luminance (e.g., a certain or predetermined luminance) due to the driving current. An opposite electrode 330 (e.g., see FIG. 3) of the organic light-emitting diode OLED may receive an electrode power supply voltage ELVSS.

Although the pixel circuit PC is illustrated as including two transistors and one storage capacitor in FIG. 2, the present disclosure is not limited thereto. For example, the number of transistors and/or the number of storage capacitors may be variously modified according to a design of the pixel circuit PC as would be understood by those having ordinary skill in the art.

FIG. 3 is a cross-sectional view schematically illustrating a part of a display apparatus, according to an embodiment.

Referring to FIG. 3, the display apparatus includes the substrate 100, the first and second thin-film transistors T1 and T2 located on the substrate 100, and an organic light-emitting diode 300 electrically connected to the first and second thin-film transistors T1 and T2. Also, the organic light-emitting display apparatus may further include various insulating layers (IL) (e.g., 111, 112, 113, 115, 118, and 119), and the storage capacitor Cst.

The substrate 100 may be formed of any of various suitable materials, such as a glass material, a metal material, or a plastic material. According to an embodiment, the substrate 100 may be a flexible substrate. The substrate 100 may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

A buffer layer 111 may be located on the substrate 100, and may reduce or prevent penetration of a foreign material, moisture, and/or external air from the bottom of the substrate 100, and may planarize or substantially planarize the substrate 100. The buffer layer 111 may include an inorganic material, such as an oxide or a nitride, an organic material, or a combination of an organic material and an inorganic material.

The buffer layer 111 may have a single layer, or a multi-layered structure including an inorganic material and an organic material. In some embodiments, a barrier layer may be further provided between the substrate 100 and the buffer layer 111 to prevent or substantially prevent penetration of external air. In some embodiments, the buffer layer 111 may include silicon oxide (SiO₂) or silicon nitride (SiN_{X}).

The first thin-film transistor T1 and/or the second thin-film transistor T2 may be located on the buffer layer 111. The first thin-film transistor T1 includes a semiconductor layer A1, a gate electrode G1, a source electrode S1, and a drain electrode D1. The second thin-film transistor T2 includes a semiconductor layer A2, a gate electrode G2, a source electrode S2, and a drain electrode D2. The first thin-film transistor T1 may be connected to the organic light-emitting diode 300, and may function as a driving thin-film transistor for driving the organic light-emitting diode 300. The second thin-film transistor T2 may be connected to the data line DL, and may function as a switching thin-film transistor. Although two thin-film transistors are illustrated in FIG. 3, the present disclosure is not limited thereto. The number of thin-film transistors may be variously modified as needed or desired. For example, anywhere from one to seven thin-film transistors may be provided as would be understood by those having ordinary skill in the art.

The semiconductor layers A1 and A2 may include amorphous silicon or

polycrystalline silicon. In another embodiment, the semiconductor layers A1 and A2 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layers A1 and A2 may include a channel region, and may further include a source region and a drain region doped with impurities.

The gate electrodes G1 and G2 are located on the semiconductor layers A1 and A2 with a first gate insulating layer 112 therebetween. The gate electrodes G1 and G2 may include molybdenum (Mo), aluminum (Al), copper (Cu), or titanium (Ti), and may have a single layer or a multi-layered structure. For example, the gate electrodes G1 and G2 may have a single-layer structure including Mo.

The first gate insulating layer 112 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A second gate insulating layer 113 may be provided to cover the gate electrodes G1 and G2. The second gate insulating layer 113 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A first storage electrode CE1 of the storage capacitor Cst may overlap with the first thin-film transistor T1. For example, the gate electrode G1 of the first thin-film transistor T1 may function as the first storage electrode CE1 of the storage capacitor Cst. However, the present disclosure is not limited thereto. The storage capacitor Cst may not overlap with the first thin-film transistor T1, and may be spaced apart from the thin-film transistors T1 and T2.

A second storage electrode CE2 of the storage capacitor Cst overlaps with the first storage electrode CE1 with the second insulating layer 113 therebetween. In this case, the second gate insulating layer 113 may function as a dielectric layer of the storage capacitor Cst. The second storage electrode CE2 may include a conductive material including molybdenum (Mo), aluminum (Al), copper (Cu), or titanium (Ti), and may have a single layer or a multi-layered structure including one or more of the above materials. For example, the second storage electrode CE2 may have a single-layer structure including Mo, or a multi-layered structure including Mo/Al/Mo.

An interlayer insulating layer 115 is formed on an entire surface of the substrate 100 to cover the second storage electrode CE2. The interlayer insulating layer 115 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The source electrodes S1 and S2 and the drain electrodes D1 and D2 are located on the interlayer insulating layer 115. Each of the source electrodes S1 and S2 and the drain electrodes D1 and D2 may include a conductive material including molybdenum (Mo), aluminum (Al), copper (Cu), or titanium (Ti), and may have a single layer or a multi-layered structure including one or more of the above materials. For example, each of the source electrodes S1 and S2 and the drain electrodes D1 and D2 may have a multi-layered structure including Ti/Al/Ti.

A planarization layer 118 may be located on the source electrodes S1 and S2 and the drain electrodes D1 and D2. The organic light-emitting diode 300 may be located on the planarization layer 118. The organic light-emitting diode 300 includes a pixel electrode 310, an intermediate layer 320 including an organic emission layer, and an opposite electrode 330.

The planarization layer 118 may have a flat or substantially flat top surface, so that the pixel electrode 310 may be formed to be flat or substantially flat. The planarization layer 118 may have a single layer or a multi-layered structure including an organic material and/or an inorganic material. The planarization layer 118 may include benzocyclobutene (BCB), polyimide, hexamethyldisiloxane (HMDSO), a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a suitable blend thereof. The planarization layer 118 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). After the planarization layer 118 is formed, chemical mechanical polishing may be performed to provide a flat or substantially flat top surface.

An opening through which any suitable one of the source electrode S1 or the drain electrode D1 of the first thin-film transistor T1 is exposed may be formed in (e.g., may penetrate) the planarization layer 118, and the pixel electrode 310 may contact the source electrode S1 or the drain electrode D1 through the opening to be electrically connected to the first thin-film transistor T1. The pixel electrode 310 includes a light-transmitting conductive layer formed of a light-transmitting conductive oxide, such as ITO, In₂O₃, or IZO, and a reflective layer formed of a metal, such as aluminum (Al) or silver (Ag). For example, the pixel electrode 310 may have a three-layered structure including ITO/Ag/ITO.

A pixel-defining film 119 may be located on the pixel electrode 310. The pixel-defining film 119 defines the pixels PX by having an opening 119OP corresponding to each sub-pixel, or in other words, an opening through which at least a central portion of the pixel electrode 310 is exposed. Also, the pixel-defining film 119 may increase a distance between an edge of the pixel electrode 310 and the opposite electrode 330, thereby, preventing or substantially preventing an arc or the like from occurring between the edge of the pixel electrode 310 and the opposite electrode 330. The pixel-defining film 119 may be formed of an organic material, such as PI or HMDSO.

In some embodiments, a spacer may be located on the pixel-defining film 119. The spacer may prevent or substantially prevent a mask damage during a mask process used to form the intermediate layer 320 of the organic light-emitting diode 300. The spacer may be formed of an organic material, such as PI or HMDSO. The spacer and the pixel-defining film 119 may be concurrently or substantially simultaneously formed by using the same material as each other. In this case, a halftone mask may be used.

The intermediate layer 320 of the organic light-emitting diode 300 may include an organic emission layer. The organic emission layer may include an organic material including a fluorescent or phosphorescent material that emits red, green, blue, or white light. Green light may be light in a wavelength band of 495 nm to 580 nm. Red light may be light in a wavelength band of 580 nm to 780 nm. Blue light may be light in a wavelength band of 400 nm to 495 nm.

The organic emission layer may be formed of a low molecular weight organic material or a high molecular weight organic material. Functional layers, such as a hole transport layer (HTL), a hole injection layer (HIL), an electron transport layer (ETL), and/or an electron injection layer (EIL), may be selectively located under and/or over the organic emission layer. The intermediate layer 320 may correspond to one of a plurality of pixel electrodes 310 (e.g., one-to-one). However, the present disclosure is not limited thereto. For example, the intermediate layer 320 may include an integrated layer disposed over the plurality of pixel electrodes 310 in common.

The opposite electrode 330 may be located over the display area DA and the peripheral area PA, and may be located on the intermediate layer 320 and the pixel-defining film 119. The opposite electrode 330 may be integrally formed with a plurality of organic light-emitting diodes 300 to correspond to the plurality of pixel electrodes 310.

The opposite electrode 330 may cover the intermediate layer 320. The opposite electrode 330 may be a light-transmitting electrode or a reflective electrode. In an embodiment, the opposite electrode 330 may have a thickness of 80 Å to 150 Å. In some embodiments, the opposite electrode 330 may be a transparent or semi-transparent electrode, and may include a metal thin film having a low work function including lithium (Li), calcium (Ca), LiF/Ca, LiF/Al, aluminum (Al), silver (Ag), magnesium (Mg), or a suitable compound thereof. Also, a transparent conductive oxide (TCO) film, such as ITO, IZO, ZnO, or In₂O₃, may be further located on the metal thin film.

Because the opposite electrode 330 may be a reflective electrode, visibility may deteriorate due to external light reflection when the display apparatus is used in a place with a lot of light. In this case, a polarizing film may be further located on the opposite electrode 330 with at least one layer therebetween. However, when the polarizing film is located to prevent or substantially prevent the reflection, a light transmittance may be reduced to 50% or less. Accordingly, greater power may be required to compensate for the luminance. Because the display apparatus according to one or more embodiments of the present disclosure includes a plurality of nano-metal patterns MP or a metal layer ML described in more detail below, a reflectance of the external light may be effectively reduced without reducing the light transmittance.

A capping layer CPL may be located on the opposite electrode 330. The capping layer CPL may improve luminous efficiency. The capping layer CPL may be a transparent layer. A thickness of the capping layer CPL may range from about 100 Å to about 5000 Å. The capping layer CPL may include an organic material, an inorganic material, or a suitable mixture thereof. Examples of the organic material may include at least one selected from the group consisting of tris-8-hydroxyquinoline aluminum (Alq3), ZnSe, (N,N′-bis(1-naphthyl)-N,N′-diphenyl-1,1″-biphenyl-4,4′-diamine) (NPB), 2,5-bis(6′-(2′,2″-bipyridyl))-1,1-dimethyl-3,4-diphenylsilole, 4′-bis[N-(1-napthyl)-N-phenyl-amion] biphenyl (α-NPD), N,N′-diphenyl-N,N′-bis(3-methylphenyl)-1,1′-biphenyl-4,4′-diamine (TPD), 1,1′-bis(di-4-tolylaminophenyl) cyclohexane (TAPC), triaryl amine derivative (EL301), 8-Quinolinolato Lithium (Liq), N(diphenyl-4-yl)9,9-dimethyl-N-(4(9-phenyl[1]9H-carbazol-3-yl)phenyl)-9H-fluorene-2-amine (HT211), and 2-(4-(9,10-di(naphthalene-2-yl)anthracene-2-yl)phenyl)-1-phenyl-1H-benzo-[D]imidazole (LG201). Examples of the inorganic material may include at least one selected from the group consisting of MoO3, ITO, IZO, SiO2, SiNx, Y2O3, WO3, and Al2O3.

A thin-film encapsulation layer 400 for sealing the display area DA may be further provided on the organic light-emitting diode 300. The thin-film encapsulation layer 400 may cover the display area DA to protect the organic light-emitting diode 300 or the like from external moisture and/or oxygen. The thin-film encapsulation layer 400 may include a first inorganic encapsulation layer 410, an organic encapsulation layer 420, and a second inorganic encapsulation layer 430.

The first inorganic encapsulation layer 410 may cover the opposite electrode 330, and may include a ceramic, a metal oxide, a metal nitride, a metal carbide, a metal oxynitride, indium oxide (In₂O₃), tin oxide (SnO₂), ITO, silicon oxide, silicon nitride, and/or silicon oxynitride. When necessary or desired, other layers, such as the capping layer CPL, may be located between the first inorganic encapsulation layer 410 and the opposite electrode 330. Because the first inorganic encapsulation layer 410 is formed along a lower structure, a top surface of the first inorganic encapsulation layer 410 may not be flat or substantially flat as shown in FIG. 3.

The organic encapsulation layer 420 covers the first inorganic encapsulation layer 410. Unlike the first inorganic encapsulation layer 410, the organic encapsulation layer 420 may have a flat or substantially flat top surface. In more detail, a portion of the organic encapsulation layer 420 corresponding to the display area DA may have a flat or substantially flat top surface. The organic encapsulation layer 420 may include at least one material selected from the group consisting of acryl, methacryl, polyester, polyethylene, polypropylene, PET, PEN, PC, PI, polyethylene sulfonate, polyoxymethylene, polyaylate, and HMDSO.

The second inorganic encapsulation layer 430 may cover the organic encapsulation layer 420, and may include a ceramic, a metal oxide, a metal nitride, a metal carbide, a metal oxynitride, indium oxide (In₂O₃), tin oxide (SnO₂), ITO, silicon oxide, silicon nitride, and/or silicon oxynitride. The second inorganic encapsulation layer 430 may prevent or substantially prevent the organic encapsulation layer 420 from being exposed to the outside, by contacting the first inorganic encapsulation layer 410 at an edge located outside the display area DA.

As such, because the thin-film encapsulation layer 400 includes the first inorganic encapsulation layer 410, the organic encapsulation layer 420, and the second inorganic encapsulation layer 430, even when cracks occur in the thin-film encapsulation layer 400, for example, due to the multi-layered structure, the cracks may not be connected between the first inorganic encapsulation layer 410 and the organic encapsulation layer 420 or between the organic encapsulation layer 420 and the second inorganic encapsulation layer 430. Accordingly, the formation of a path through which external moisture and/or oxygen may penetrate into the display area DA may be prevented, minimized, or reduced.

Although the thin-film encapsulation layer 400 is used as an encapsulation member for sealing the organic light-emitting diode 300 in the present embodiment, the present disclosure is not limited thereto. For example, a sealing substrate attached to the substrate 100 by a sealant or a frit may be used as a member (e.g., an encapsulation member) for sealing the organic light-emitting diode 300.

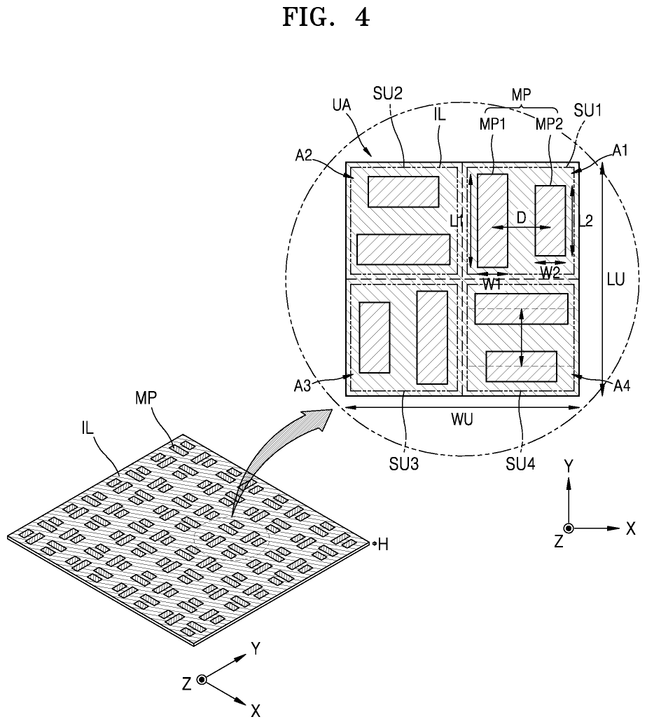

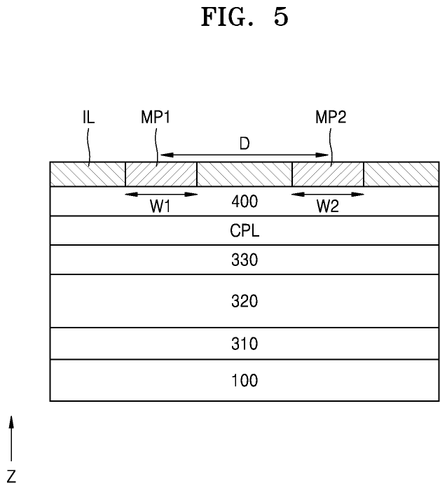

FIG. 4 is a perspective view schematically illustrating an embodiment of the metal patterns MP. FIG. 5 is a cross-sectional view schematically illustrating a portion of a display apparatus, according to an embodiment.

Referring to FIGS. 4 and 5 together, the display apparatus according to an embodiment may include a plurality of metal patterns MP, and an insulating layer IL buried in a separation area between the metal patterns MP.

The plurality of metal patterns MP may be spaced apart from the opposite electrode 330 by a suitable interval (e.g., a certain or predetermined interval). Certain layers may be located between the plurality of metal patterns MP and the opposite electrode 330. For example, the plurality of metal patterns MP may be located on the capping layer CPL and/or the thin-film encapsulation layer 400. A thickness H of each of the plurality of metal patterns MP may be less than a wavelength of visible light. The thickness H of each of the plurality of metal patterns MP may be 800 nm or less, and in more detail, may be 100 nm or less.

Each of the plurality of metal patterns MP may have a suitable shape (e.g., a certain or predetermined shape). For example, each of the plurality of metal patterns MP may have a rectangular shape in a plan view. In this case, each of the plurality of metal patterns MP may be provided in a rectangular parallelepiped shape. The plurality of metal patterns MP may be spaced apart from each other.

The plurality of metal patterns MP may constitute a metal unit area UA. In other words, the metal unit area UA may include the plurality of metal patterns MP that are spaced apart from each other. The metal unit area UA may be divided into quadrants. A sub-unit including some of the plurality of metal patterns MP may be located with a suitable arrangement relationship (e.g., a certain or predetermined arrangement relationship) in each of the quadrants of the metal unit area UA. For example, a sub-unit may be rotated by 90 degrees for (e.g., and located in) each of the quadrants of the metal unit area UA.

Referring to FIG. 4, in an embodiment, the plurality of metal patterns MP may include a first metal pattern MP1 and a second metal pattern MP2. The first metal pattern MP1 and the second metal pattern MP2 may constitute a first sub-unit SU1. The first sub-unit SU1 may be located in a first quadrant A1 of the metal unit area UA. A second sub-unit SU2 may be located in a second quadrant A2. A third sub-unit SU3 may be located in a third quadrant A3. A fourth sub-unit SU4 may be located in a fourth quadrant. The second sub-unit SU2 may have a shape obtained by rotating the first sub-unit SU1 by 90 degrees in a counterclockwise direction. The third sub-unit SU3 may have a shape obtained by rotating the second sub-unit SU2 by 90 degrees. The fourth sub-unit SU4 may have a shape obtained by rotating the third sub-unit SU3. In other words, the second sub-unit SU2, the third sub-unit SU3, and the fourth sub-unit SU4 may have shapes obtained by rotating the first sub-unit SU1 by 90 degrees, 180 degrees, and 270 degrees in the counterclockwise direction, respectively.

The metal unit area UA may be repeatedly arranged along a first direction (e.g., the x-direction) and/or a second direction (e.g., the y-direction) on the thin-film encapsulation layer 400. Accordingly, a plurality of metal unit areas UA may be provided. A spatial repeat period between the metal unit areas UA may be equal to or greater than 300 nm, and equal to or less than 1500 nm. In other words, a width WU in the first direction (e.g., the x-direction) and a width LU in the second direction (e.g., the y-direction) of one metal unit area UA, which is repeatedly arranged, may be equal to or greater than 300 nm and equal to or less than 1500 nm.

In an embodiment, each of the first metal pattern MP1 and the second metal pattern MP2 may have a rectangular parallelepiped shape. In a plan view, each of the first metal pattern MP1 and the second metal pattern MP2 may have a rectangular shape. In a plan view, the area of the first metal pattern MP1 may be greater than the area of the second metal pattern MP2. A plan view may refer to a view of an object portion taken in a direction (e.g., the z-direction) perpendicular to or substantially perpendicular to the substrate 100.

The first metal pattern MP1 and the second metal pattern MP2 may be located parallel to or substantially parallel to each other in the first direction (e.g., the x-direction). An interval D between the first metal pattern MP1 and the second metal pattern MP2 may be equal to or greater than 50 nm, and equal to or less than 500 nm. The interval D between the first metal pattern MP1 and the second metal pattern MP2 may refer to an interval, in the first direction (e.g., the x-direction), between a virtual line that extends in the second direction (e.g., the y-direction) and passes through the center of the first metal pattern MP1 and a virtual line that extends in the second direction (e.g., the y-direction) and passes through the center of the second metal pattern MP2.

The first metal pattern MP1 and the second metal pattern MP2 may extend in the second direction (e.g., the y-direction). A width W1 of the first metal pattern MP1 in the first direction (e.g., the x-direction) and a width W2 of the second metal pattern MP2 in the first direction (e.g., the x-direction) may each be equal to or greater than 20 nm, and equal to or less than 300 nm. The widths W1 and W2 of the first metal pattern MP1 and the second metal pattern MP2 in the first direction (e.g., the x-direction) may be the same or substantially the same as each other. A length L1 of the first metal pattern MP1 in the second direction (e.g., the y-direction) may be greater than a length L2 of the second metal pattern MP2 in the second direction (e.g., the y-direction). The length L1 of the first metal pattern MP1 may be equal to or greater than 100 nm, and equal to or less than 650 nm. The length L2 of the second metal pattern MP2 may be equal to or greater than 50 nm, and equal to or less than 600 nm.

Each of the plurality of metal patterns MP may include a metal material having a negative dielectric function (e.g., ε′<0). Each of the plurality of metal patterns MP may include at least one of silver (Ag), gold (Au), aluminum (Al), tantalum (Ta), or nickel (Ni).

The insulating layer IL may be buried in a separation area between the plurality of metal patterns MP. In other words, the insulating layer IL may fill an area between the plurality of metal patterns MP. The insulating layer IL may be a dielectric. The insulating layer IL may include an organic material, an inorganic material, or a suitable mixture thereof. The insulating layer IL may include at least one of SiO₂, CaF₂, MgF₂, LiF, SiNx, SiCN, SiON, TaₓO_{y}, TiOx HfO₂, or ZrO₂. The insulating layer IL may include the same or substantially the same material as that of the capping layer CPL.

The display apparatus according to an embodiment may include the opposite electrode 330, the capping layer CPL, the plurality of metal patterns MP that are spaced apart from each other, and the insulating layer IL buried in a separation area between the plurality of metal patterns MP. A thickness, a width, a length, a shape, and a material of the metal patterns MP may be the same or substantially the same as those described above. In more detail, a thickness of the metal patterns MP may be less than a wavelength of visible light. In an embodiment, a thickness of the metal patterns MP may be equal to or less than 100 nm. The plurality of metal patterns MP and the insulating layer IL may form a meta-surface to reduce external light reflection. The meta-surface is a two-dimensional surface including a meta-material, and the meta-material may refer to any suitable material obtained by artificially changing an arrangement and a structure of a natural material to have properties that are not found in nature.

Because the insulating layer IL that is a dielectric is buried in an area between the plurality of metal patterns MP, a surface plasmon may be generated on surfaces of the plurality of metal patterns MP, and may interact with external light to reduce a reflectance. Light incident from the outside may excite a localized surface plasmon due to the plurality of metal patterns MP, and thus, external light may be absorbed.

Also, light incident from the outside may interact between the plurality of metal patterns MP and the opposite electrode 330 to cause an interference effect, and may excite surface plasmon polaritons, and thus, external light may be absorbed. For active interaction between the plurality of metal patterns MP and the opposite electrode 330, the plurality of metal patterns MP and the opposite electrode 330 may be spaced apart from each other by an appropriate interval. Accordingly, the capping layer CPL and/or the thin-film encapsulation layer 400 may be located between the plurality of metal patterns MP and the opposite electrode 330.

When the plurality of metal patterns MP have the shape, width, length, and arrangement described above, the meta-surface formed by the plurality of metal patterns MP and the insulating layer IL may more effectively absorb light incident from the outside than the light generated by the display element.

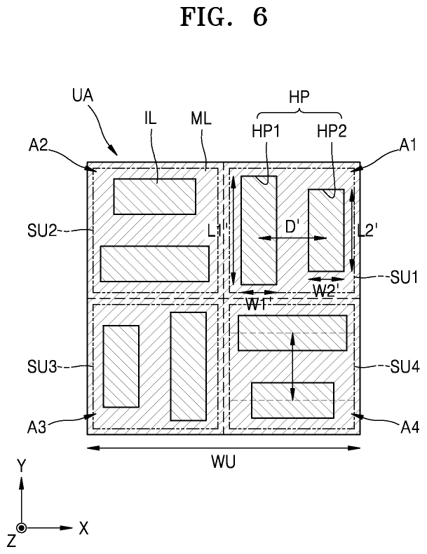

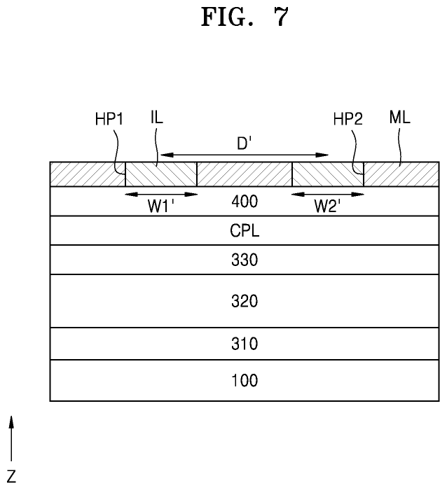

FIG. 6 is a plan view schematically illustrating an example of through-patterns HP. FIG. 7 is a cross-sectional view schematically illustrating a portion of a display apparatus, according to an embodiment.

Referring to FIGS. 6 and 7 together, the display apparatus according to an embodiment may include the metal layer ML including a plurality of through-patterns HP, and the insulating layer IL buried in the through-patterns HP.

The metal layer ML including the plurality of through-patterns HP and the insulating layer IL filling the through-patterns as illustrated in FIGS. 6 and 7 may have shapes obtained by reversing those of the plurality of metal patterns MP and the insulating layer IL described above with reference to FIGS. 4 and 5. In other words, in FIGS. 6 and 7, the through-patterns HP may be located for the insulating layer IL to be buried at positions corresponding to those of the metal patterns MP described above with reference to FIGS. 4 and 5, and a metal material may be located at a position corresponding to that of the insulating layer IL described above with reference to FIGS. 4 and 5.

The metal layer ML may be spaced apart from the opposite electrode 330 by a suitable interval (e.g., a certain or predetermined interval). The capping layer CPL and/or the thin-film encapsulation layer 400 may be located between the metal layer ML and the opposite electrode 330. A thickness of the metal layer ML may be less than a wavelength of visible light. A thickness of the metal layer ML may be equal to or less than 800 nm, and in more detail, may be equal to or less than 100 nm. In other words, a depth of each of the plurality of through-patterns HP may be less than a wavelength of visible light, such as equal to or less than 800 nm, or equal to or less than 100 nm.

The metal layer ML may include the plurality of through-patterns HP, each having a suitable shape (e.g., a certain or predetermined shape). Each of the plurality of through-patterns HP may have a rectangular shape in a plan view. In this case, each of the plurality of through-patterns HP may have a rectangular parallelepiped shape. The plurality of through-patterns HP may be spaced apart from each other.

The plurality of through-patterns HP may constitute the metal unit area UA. In other words, the metal unit area UA may include the plurality of through-patterns HP that are spaced apart from each other. The metal unit area UA may be divided into quadrants. A sub-unit including some of the plurality of through-patterns HP may be located with a suitable arrangement relationship (e.g., a certain or predetermined arrangement relationship) in each of the quadrants of the metal unit area UA. For example, a sub-unit may be rotated by 90 degrees for (e.g., and located in) each of the quadrants of the metal unit area UA.

Referring to FIG. 6, in an embodiment, the plurality of through-patterns HP may include a first through-pattern HP1 and a second through-pattern HP2. The first through-pattern HP1 and the second through-pattern HP2 may constitute a first sub-unit SU1. The first sub-unit SU1 may be located in a first quadrant A1 of the metal unit area UA. A second sub-unit SU2 may be located in a second quadrant A2. A third sub-unit SU3 may be located in a third quadrant A3. A fourth sub-unit SU4 may be located in a fourth quadrant. The second sub-unit SU2 may have a shape obtained by rotating that of the first sub-unit SU1 by 90 degrees in the counterclockwise direction. The third sub-unit SU3 may have a shape obtained by rotating that of the second sub-unit SU2 by 90 degrees. The fourth sub-unit SU4 may have a shape obtained by rotating that of the third sub-unit SU3. In other words, the second sub-unit SU2, the third sub-unit SU3, and the fourth sub-unit SU4 may have shapes obtained by rotating that of the first sub-unit SU1 by 90 degrees, 180 degrees, and 270 degrees in the counterclockwise direction, respectively.

The metal unit area UA may be repeatedly arranged on the thin-film encapsulation layer 400 along the first direction (e.g., the x-direction) and/or the second direction (e.g., the y-direction). Accordingly, a plurality of metal unit areas UA may be provided. A spatial repeat period between the metal unit areas UA may be equal to or greater than 300 nm, and equal to or less than 1500 nm. In other words, a width WU in the first direction (e.g., the x-direction) and a width LU in the second direction (e.g., the y-direction) of one metal unit area UA, which is repeatedly arranged, may be equal to or greater than 300 nm, and equal to or less than 1500 nm.

In an embodiment, each of the first through-pattern HP1 and the second through-pattern HP2 may have a rectangular parallelepiped shape. In a plan view, each of the first through-pattern HP1 and the second through-pattern HP2 may have a rectangular shape. In a plan view, the area of the first through-pattern HP1 may be greater than the area of the second through-pattern HP2. A plan view may refer to a view of an object portion taken in a direction (e.g., the z-direction) perpendicular to or substantially perpendicular to the substrate 100.

The first through-pattern HP1 and the second through-pattern HP2 may be parallel to or substantially parallel to each other in the first direction (e.g., the x-direction). An interval D′ between the first through-pattern HP1 and the second through-pattern HP2 may be equal to or greater than 50 nm, and equal to or less than 500 nm. The interval D′ between the first through-pattern HP1 and the second through-pattern HP2 may refer to an interval, in the first direction (e.g., the x-direction), between a virtual line that extends in the second direction (e.g., the y-direction) and passes through the center of the first through-pattern HP1 and a virtual line that extends in the second direction (e.g., the y-direction) and passes through the center of the second through-pattern HP2.

The first through-pattern HP1 and the second through-pattern HP2 may extend in the second direction (e.g., the y-direction). A width W1′ of the first through-pattern HP1 and a width W2′ of the second through-pattern HP2 in the first direction (e.g., the x-direction) may each be equal to or greater than 20 nm, and equal to or less than 300 nm. The widths W1′ and W2′ of the first through-pattern HP1 and the second through-pattern HP2 in the first direction (e.g., the x-direction) may be the same or substantially the same as each other. A length L1′ of the first through-pattern HP1 in the second direction (e.g., the y-direction) may be greater than a length L2′ of the second through-pattern HP2 in the second direction (e.g., the y-direction). The length L1′ of the first through-pattern HP1 may be equal to or greater than 100 nm, and equal to or less than 650 nm. The length L2′ of the second through-pattern HP2 may be equal to or greater than 50 nm, and equal to or less than 600 nm.

The metal layer ML including the plurality of through-patterns HP may include a metal material having a negative dielectric function (e.g., ¿′<0). The metal layer ML may include at least one of silver (Ag), gold (Au), aluminum (Al), tantalum (Ta), or nickel (Ni).

The insulating layer IL may be buried in the plurality of through-patterns HP. The insulating layer IL that is a dielectric may fill the plurality of through-patterns HP of the metal layer ML. The insulating layer IL may include an organic material, an inorganic material, or a suitable mixture thereof. The insulating layer IL may include at least one of SiO₂, CaF₂, MgF₂, LiF, SiNx, SiCN, SION, TaₓO_{y}, TiOx HfO₂, or ZrO₂. The insulating layer IL may include the same or substantially the same material as that of the capping layer CPL.

The display apparatus according to an embodiment may include the opposite electrode 330, the capping layer CPL, the metal layer ML including the plurality of through-patterns HP, and the insulating layer IL buried in the plurality of through-patterns HP. A depth, a width, a length, and a shape of the plurality of through-patterns HP may be the same or substantially the same those described above. In more detail, a depth of the through-patterns HP may be less than a wavelength of visible light. A depth of the through-patterns HP may be equal to or greater than 100 nm. The metal layer ML including the plurality of through-patterns HP and the insulating layer IL filling the through-patterns HP may form a meta-surface to reduce external light reflection, similarly to that described above with reference to FIGS. 4 and 5.

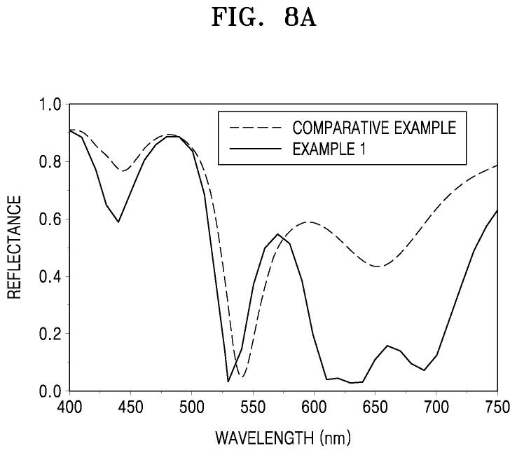

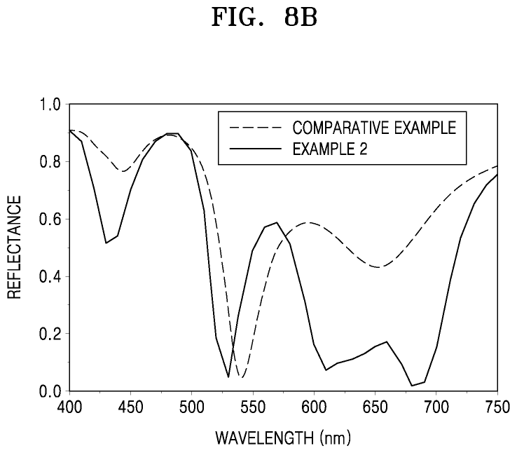

FIGS. 8A and 8B are simulation graphs illustrating the reflectance of a display apparatus of an embodiment and the reflectance of a comparative example. Example 1 of FIG. 8A is an embodiment in which a meta-surface including the plurality of metal patterns MP that are spaced apart from each other is formed. Example 2 of FIG. 8B is an embodiment in which a meta-surface including the metal layer ML including the plurality of through-patterns HP is formed. The comparative example of FIGS. 8A and 8B is an example in which the plurality of metal patterns MP and the metal layer ML, such as those in Examples 1 and 2, are removed or omitted.

Referring to FIGS. 8A and 8B, Examples 1 and 2 generally have a lower reflectance than that of the comparative example in a wavelength band of 400 nm to 750 nm. In more detail, in a wavelength band of 550 nm to 750 nm, Examples 1 and 2 have a significantly lower reflectance than that of the comparative example. However, the present disclosure is not limited thereto. In Example 1, a range of wavelength bands having a low reflectance may vary according to a size and a thickness of the metal patterns MP, and a spatial repeat period between the metal unit areas UA. Also, in Example 2, a range of wavelength bands having a low reflectance may vary according to a size and a thickness of the through-patterns HP, and a spatial repeat period between the metal unit areas UA.

In Example 1, for example, the metal patterns MP included in the second to fourth sub-units SU2, SU3, and SU4 have the same sizes as those of the metal patterns MP included in the first sub-unit SU1, but have shapes obtained by rotating them by certain angles. Unlike this, in an embodiment, the metal patterns MP included in the second to fourth sub-units SU2, SU3, and SU4 may have different widths and lengths from those of the metal patterns MP included in the first sub-unit SU1. In this case, a significantly lower reflectance may be achieved in a wavelength band different from the wavelength band of 550 nm to 750 nm of Example 1. Similarly, a wavelength band having a low reflectance may vary according to a thickness of the metal patterns MP, and a spatial repeat period between the metal unit areas UA.

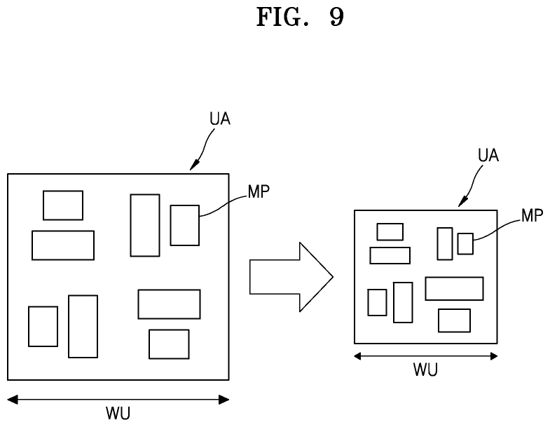

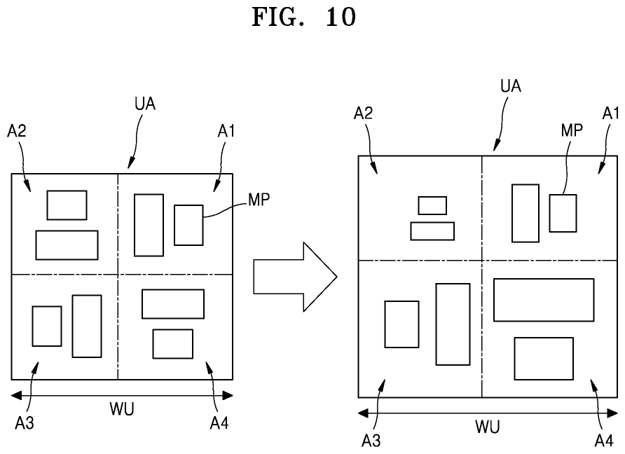

FIGS. 9 and 10 are plan views schematically illustrating an example of the metal patterns MP. FIGS. 9 and 10 show a change in the width WU of the metal unit area UA or a size of the metal patterns MP. A reflectance according to a wavelength band may be adjusted by changing the width of the metal unit area UA and/or the size of the metal patterns MP.

FIG. 9 shows a change in the width WU of the metal unit area UA. A display apparatus in which the metal unit area UA illustrated on the right of FIG. 9 (the right metal unit area UA) is repeatedly arranged and a display apparatus in which the metal unit area UA illustrated on the left of FIG. 9 (the left metal unit area UA) is repeatedly arranged may have different reflectances from each other according to the same wavelength band. The width WU of the right metal unit area UA is less than the width WU of the left metal unit area UA. In other words, the right metal unit area UA may have a spatial repeat period less than that of the left metal unit area UA. In an embodiment, the width WU of the right metal unit area UA may be half the width WU of the left metal unit area UA. In an embodiment, four right metal unit areas UA may correspond to the quadrants of the left metal unit area UA, respectively, and one left metal unit area UA and four right metal unit areas UA may be alternately and repeatedly arranged on the thin-film encapsulation layer 400 of the display apparatus.

FIG. 10 shows a change in a size of the metal patterns MP included in the metal unit area UA. In the metal unit area UA illustrated on the left of FIG. 10 (the left metal unit area UA), the metal patterns MP located in first to fourth quadrants have the same or substantially the same size as one another, and only the shapes obtained by rotating by different angles are illustrated. Unlike this, in the metal unit area UA illustrated on the right of FIG. 10 (the right metal unit area UA), the metal patterns MP located in the first to fourth quadrants A1, A2, A3, and A4 may have different widths and lengths from one another. In this case, a display apparatus including the left metal unit area UA and a display apparatus including the right metal unit area UA may have different reflection characteristics from each other.

Unlike that illustrated in FIG. 10 in which each of the metal patterns MP has a rectangular shape, in an embodiment, the metal patterns MP included in one metal unit area UA may have different shapes from one another. In an embodiment, the metal patterns MP included in one metal unit area UA may have different thicknesses from one another. A change in a reflectance according to a wavelength band of light may be controlled by adjusting a width, a length, a thickness, and/or a shape of the metal patterns MP included in one metal unit area UA.

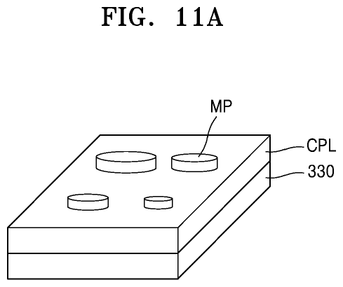

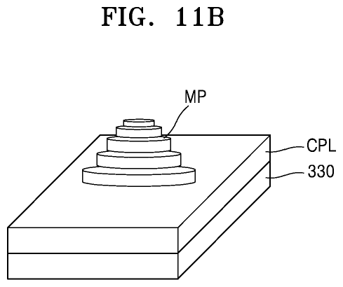

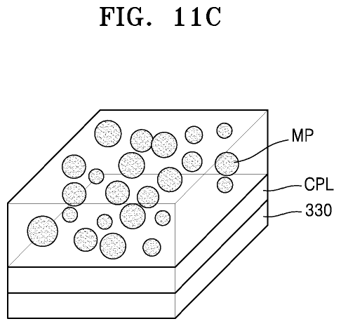

FIGS. 11A through 11C are perspective views schematically illustrating some examples of metal patterns. For convenience of illustration, one metal unit area UA including the metal patterns MP is shown. Referring to FIGS. 11A to 11C, the plurality of metal patterns MP may have a cylindrical shape, a stacked cylindrical shape, or a spherical shape, in addition to a rectangular parallelepiped shape.

A height of one cylinder illustrated in FIGS. 11A and 11C may range from 5 nm to 100 nm. A diameter of a largest cylinder may range from 20 nm to 650 nm. A diameter of one sphere illustrated in FIG. 11C may range from 5 nm to 100 nm.

While a display apparatus has been mainly described, the present disclosure is not limited thereto. For example, a method of manufacturing the display apparatus may also fall within the spirit and scope of the present disclosure.

According to one or more embodiments described above, a display apparatus having excellent anti-reflection characteristics may be provided. However, the spirit and scope of the present disclosure are not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate;
a display element on the substrate, and comprising a pixel electrode, an emission layer, and an opposite electrode;
a capping layer on the display element;
a metal unit area comprising a plurality of metal patterns spaced from each other on the capping layer, each of the plurality of metal patterns having a thickness less than a wavelength of visible light; and
an insulating layer buried in a separation area between the plurality of metal patterns.

2. The display apparatus of claim 1, wherein the metal unit area is repeatedly arranged along a first direction, and a second direction crossing the first direction, and
wherein a width of the metal unit area that is repeatedly arranged is equal to or greater than 300 nm, and equal to or less than 1500 nm.

3. The display apparatus of claim 1, wherein the plurality of metal patterns comprises a first metal pattern and a second metal pattern adjacent to each other in a first direction, each having a rectangular shape in a plan view.

4. The display apparatus of claim 3, wherein the metal unit area is divided into first to fourth quadrants,
wherein a first sub-unit comprising the first metal pattern and the second metal pattern is located in the first quadrant,
wherein a second sub-unit obtained by rotating the first sub-unit by 90 degrees counterclockwise is located in the second quadrant,
wherein a third sub-unit obtained by rotating the first sub-unit by 180 degrees counterclockwise is located in the third quadrant, and
wherein a fourth sub-unit obtained by rotating the first sub-unit by 270 degrees counterclockwise is located in the fourth quadrant.

5. The display apparatus of claim 4, wherein an interval between the first metal pattern and the second metal pattern is equal to or greater than 50 nm, and equal to or less than 500 nm.

6. The display apparatus of claim 4, wherein the thickness of each of the first metal pattern and the second metal pattern is equal to or greater than 5 nm, and equal to or less than 100 nm.

7. The display apparatus of claim 4, wherein:
a width of each of the first metal pattern and the second metal pattern in the first direction is equal to or greater than 20 nm, and equal to or less than 300 nm;
a length of the first metal pattern in a second direction crossing the first direction is equal to or greater than 100 nm, and equal to or less than 650 nm; and
a length of the second metal pattern in the second direction is equal to or greater than 50 nm, and equal to or less than 600 nm.

8. The display apparatus of claim 1, wherein each of the plurality of metal patterns has a spherical shape, a cylindrical shape, or a stacked cylindrical shape.

9. The display apparatus of claim 1, wherein each of the plurality of metal patterns comprises silver (Ag), gold (Au), aluminum (Al), tantalum (Ta), nickel (Ni), or a combination thereof.

10. The display apparatus of claim 1, further comprising a thin-film encapsulation layer between the capping layer and the plurality of metal patterns.

11. A display apparatus comprising:
a substrate;
a display element on the substrate, and comprising a pixel electrode, an emission layer, and an opposite electrode;
a capping layer on the display element;
a metal layer on the capping layer, and comprising a metal unit area comprising a plurality of through-patterns, each having a depth less than a wavelength of visible light; and
an insulating layer buried in the plurality of through-patterns.

12. The display apparatus of claim 11, wherein the metal unit area is repeatedly arranged along a first direction, and a second direction crossing the first direction, and
wherein a width of the metal unit area that is repeatedly arranged is equal to or greater than 300 nm, and equal to or less than 1500 nm.

13. The display apparatus of claim 11, wherein the plurality of through-patterns comprises a first through-pattern and a second through-pattern adjacent to each other in a first direction, each having a rectangular shape in a plan view.

14. The display apparatus of claim 13, wherein the metal unit area is divided into first to fourth quadrants,
wherein a first sub-unit comprising the first through-pattern and the second through-pattern is located in the first quadrant,
wherein a second sub-unit obtained by rotating the first sub-unit by 90 degrees counterclockwise is located in the second quadrant,
wherein a third sub-unit obtained by rotating the first sub-unit by 180 degrees counterclockwise is located in the third quadrant, and
wherein a fourth sub-unit obtained by rotating the first sub-unit by 270 degrees counterclockwise is located in the fourth quadrant.

15. The display apparatus of claim 14, wherein an interval between the first through-pattern and the second through-pattern is equal to or greater than 50 nm, and equal to or less than 500 nm.

16. The display apparatus of claim 14, wherein the depth of each of the first through-pattern and the second through-pattern is equal to or greater than 5 nm, and equal to or less than 100 nm.

17. The display apparatus of claim 14, wherein:
a width of each of the first through-pattern and the second through-pattern in the first direction is equal to or greater than 20 nm, and equal to or less than 300 nm;
a length of the first through-pattern in a second direction crossing the first direction is equal to or greater than 100 nm, and equal to or less than 650 nm; and
a length of the second through-pattern in the second direction is equal to or greater than 50 nm, and equal to or less than 600 nm.

18. The display apparatus of claim 11, wherein each of the plurality of through-patterns has a spherical shape, a cylindrical shape, or a stacked cylindrical shape.

19. The display apparatus of claim 11, wherein the metal layer comprises silver (Ag), gold (Au), aluminum (Al), tantalum (Ta), nickel (Ni), or a combination thereof.

20. The display apparatus of claim 11, further comprising a thin-film encapsulation layer between the capping layer and the metal layer.
